(19) United States
(12) Patent Application Publication
(10) Pub. No.: US 2025/0027769 A1
(43) Pub. Date: Jan. 23, 2025

(54) INVERSION METHOD OF RIVER COURSE DEPTH BASED ON MATHEMATICAL MODEL AND REMOTE SENSING OF WATER DEPTH-WATER SURFACE AREA

(71) Applicants: WUHAN UNIVERSITY, Wuhan (CN); CHINA YANGTZE POWER CO., LTD., Yichang (CN)

(72) Inventors: Yanjun ZHANG, Wuhan (CN); Xuetao ZENG, Wuhan (CN); Xinbo LIU, Yichang (CN); Zhengfeng BAO, Yichang (CN); Hui CAO, Yichang (CN); Yifan WANG, Wuhan (CN); Yufeng REN, Yichang (CN); Jiahui YANG, Wuhan (CN)

(73) Assignees: WUHAN UNIVERSITY, Wuhan (CN); CHINA YANGTZE POWER CO., LTD., Yichang (CN)

(21) Appl. No.: 18/678,701

(22) Filed: May 30, 2024

Related U.S. Application Data
(63) Continuation of application No. PCT/CN2024/074822, filed on Jan. 31, 2024.

(30) Foreign Application Priority Data
Jul. 21, 2023 (CN) 202310907653.7

(51) Int. Cl. G01C 13/00

(52) U.S. Cl. CPC G01C 13/008

(57) ABSTRACT

An inversion method of river course depth based on a mathematical model and remote sensing of water depth-water surface area includes the following steps: constructing the first mathematical model; calculating the relation function between the water flowing cross-section area, the triangle area at two sides and the water depth as well as the flow path, and substituting the relation functions into the first mathematical model to obtain the second mathematical model; transforming the second mathematical model into the mathematical model of water level-water surface area; solving the unknowns in the mathematical model, and substituting the unknowns into the second mathematical model to obtain the third mathematical model; and substituting the water surface area extracted by the remote sensing into the third mathematical model to obtain the water depth of the river course.

### CROSS REFERENCE TO THE RELATED APPLICATIONS

This application is the continuation application of International Application No. PCT/CN2024/074822, filed on Jan. 31, 2024, which is based upon and claims priority to Chinese Patent Application No. 202310907653.7, filed on Jul. 21, 2023, the entire contents of which are incorporated herein by reference.

### TECHNICAL FIELD

The present disclosure relates to the technical field of inversion of river course depth, in particular to an inversion method of river course depth based on a mathematical model and remote sensing of water depth-water surface area.

### BACKGROUND

A sounding rod, a sounding hammer and an echo sounder are utilized to measure the bathymetry of a conventional river. A sounding rod and a sounding hammer are two tools utilized simultaneously in the actual sounding process, but they will be affected by water depth, flow rate, weather conditions and other factors, resulting in large errors; the measurement results of an echo sounder in still water and clear water are more reliable, and the measurement accuracy is significantly reduced in rivers with high sediment concent.

With the continuous enrichment of satellite remote sensing data, the use of remote sensing for water depth inversion has attracted more and more attention. Scholars use one or more bands to establish the relationship with the water depth for water depth inversion. However, compared with the ocean, the water depth remote sensing inversion of inland water will be disturbed by suspended sediment in the water body, which makes it more difficult to use the relationship between band and water depth for inversion. In addition, the measured water depth is accidental, and the water depth at the measured point is less representative due to the complex underwater terrain.

Therefore, it is an urgent problem for those skilled in the art to solve how to provide an inversion method of river course depth based on a mathematical model and remote sensing of water depth-water surface area, which can overcome the difficulty of using bands to invert the water depth of a water body with high sediment content and improve the representativeness of the water depth value.

### SUMMARY

In view of this, the present disclosure provides an inversion method of river course depth based on a mathematical model and remote sensing of water depth-water surface area.

In order to achieve the above effects, the present disclosure adopts the following technical solutions.

An inversion method of river course depth based on a mathematical model and remote sensing of water depth-water surface area includes:
Step (1), constructing the first mathematical model of water depth-water surface area of a river course;
Step (2), calculating the relation function between the water flowing cross-section area and the water depth as well as the flow path of the river course and a relation function between the area of the triangle at two sides and the water depth as well as the flow path of the river course based on the type of the river course, and substituting the relation functions into the first mathematical model of water depth-water surface area to obtain the second mathematical model of water depth-water surface area;
Step (3), transforming the second mathematical model of water depth-water surface area into the mathematical model of water level-water surface area based on the relationship between water level and water depth; solving the unknowns in the mathematical model of water level-water surface area combined with the relationship between water level and water surface area obtained by remote sensing, and substituting the unknowns into the second mathematical model of water depth-water surface area to obtain the third mathematical model of water depth-water surface area; and
Step (4), substituting the water surface area extracted by the remote sensing into the third mathematical model of water depth-water surface area to obtain the water depth of the river course.

Optionally, in the Step (1), the first mathematical model of water depth-water surface area is as follows:

$$H = ( {\int }_{0}^{L} {A}_{1} ( H , x ) dx + {\int }_{0}^{L} ( {A}_{2} ( H , x ) + {A}_{3} ( H , x ) ) dx ) / A ;$$

wherein, H is the water depth, L is the length of a river course, A₁(H, x) is the water flowing cross-section area; x is the flow path; A₂(H, x) and A₃(H, x) are the area of the triangle at two sides; A is the water surface area.

Optionally, in the Step (2), the type of the river course includes the trapezoidal cross-section river course and the triangular river course.

Optionally, the relation function between the water flowing cross-section area and the water depth as well as the flow path of the trapezoidal cross-section river course is as follows:

$${A}_{1} ( H , x ) = ( w + mH ) * H ;$$

wherein, A₁(H, x) is the water flowing cross-section area; w is the bottom width of a river course; m is the slope coefficient of a river course; H is the water depth.

The relation function between the area of the triangle at two sides and the water depth as well as the flow path of the trapezoidal cross-section river course is as follows:

$${A}_{2} ( H , x ) = {A}_{3} ( H , x ) = \frac{1}{2} * H * mH ;$$

wherein, A₂(H, x) and A₃(H, x) are the area of the triangle at two sides.

Optionally, the relation function between the water flowing cross-section area and the water depth as well as the flow path of the triangular river course is as follows:

$${A}_{1} ( H , x ) = ( mH ) * H ;$$

wherein, A₁(H, x) is the water flowing cross-section area; m is the slope coefficient of a river course; H is the water depth.

The relation function between the area of the triangle at two sides and the water depth as well as the flow path of the triangular river course is as follows:

$${A}_{2} ( H , x ) = {A}_{3} ( H , x ) = \frac{1}{2} * H * mH ;$$

wherein, A₂(H, x) and A₃(H, x) are the area of the triangle at two sides.

Optionally, the second mathematical model of water depth-water surface area of the trapezoidal cross-section river course is as follows:

$$H = \frac{A - wL}{2 mL} ;$$

wherein, H is the water depth; A is the water surface area; w is the bottom width of a river course; L is the length of a river course; m is the slope coefficient of a river course.

Optionally, the second mathematical model of water depth-water surface area of the triangular river course is as follows:

$$H = \frac{A}{2 mL} ;$$

wherein, H is the water depth; A is the water surface area; m is the slope coefficient of a river course; L is the length of a river course.

Optionally, in the Step (3), the relationship between water level and water depth is as follows:

$$Z = H + {Z}_{0} ;$$

wherein, Z is the water level; H is the water depth; Z₀ is the bottom elevation of trench.

Optionally, in the Step (3), the solving the unknowns in the mathematical model of water level-water surface area combined with the relationship between water level and water surface area obtained by remote sensing based on the relationship between water level and water depth specifically is as follows:
assuming that the corresponding parts of the mathematical model of water level-water surface area and the relationship between water level and water surface area are equal, solve for the unknowns in the mathematical model of water level-water surface area.

According to the above technical solutions, compared with the prior art, the present disclosure provides an inversion method of river course depth based on a mathematical model and remote sensing of water depth-water surface area. A mathematical model of water depth-water surface area is constructed based on the relationship between the water flowing cross-section area and the water depth as well as the flow path and the relationship between the area of the triangle at two sides and the water depth as well as the flow path, the unknowns in the mathematical model are solved by combining with the relationship between water level and water surface area obtained by remote sensing to obtain the relationship between the average water depth and water surface area. Based on this, by substituting the water surface area, the inversion of the average water depth of the river course can be achieved. Is not only improves the representativeness of water depth values, but also overcomes the difficulty of utilizing wave bands to invert the water depth of high sediment content water bodies.

### BRIEF DESCRIPTION OF THE DRAWINGS

In order to more clearly illustrate the embodiments of the present disclosure or technical solutions in the related art, the accompanying drawings used in the embodiments or the related art will now be described briefly. It is obvious that the drawings in the following description are only the embodiment of the disclosure, and that those skilled in the art can obtain other drawings from these drawings without any creative efforts.

FIG. 1 is a flowchart of the method of the present disclosure.

FIG. 2 is a schematic diagram of a general river course of the present disclosure.

FIG. 3 is a schematic diagram of a trapezoidal cross-section river course of the present disclosure. and

FIG. 4 is a schematic diagram of a triangular river course of the present disclosure.

### DETAILED DESCRIPTION OF THE EMBODIMENTS

In the following, the technical solutions in the embodiments of the present disclosure will be clearly and completely described with reference to the drawings in the embodiments of the present disclosure. Obviously, the described embodiments are only a part of the embodiments of the present disclosure, but not all the embodiments thereof. Based on the embodiments of the present disclosure, all other embodiments obtained by those skilled in the art without any creative efforts shall fall within the scope of the present disclosure.

### Example 1

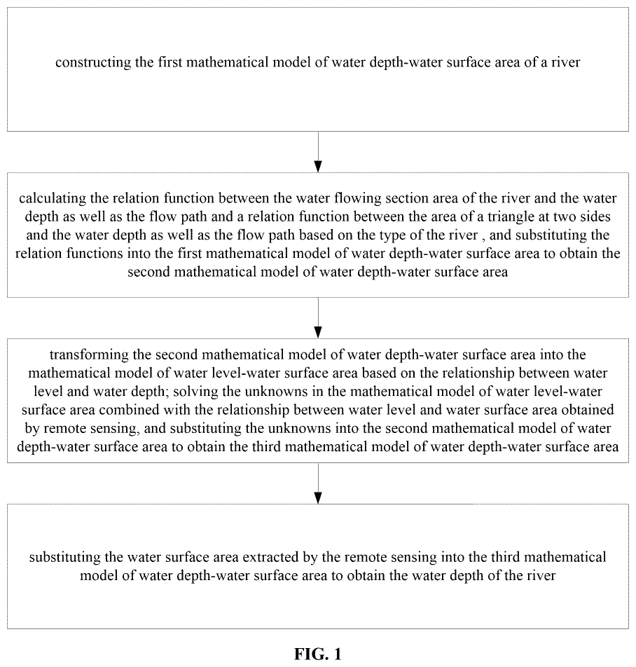

Example 1 of the present disclosure discloses an inversion method of river course depth based on a mathematical model and remote sensing of water depth-water surface area, as shown in FIG. 1, including:

Step (1), the first mathematical model of water depth-water surface area of a river is constructed.

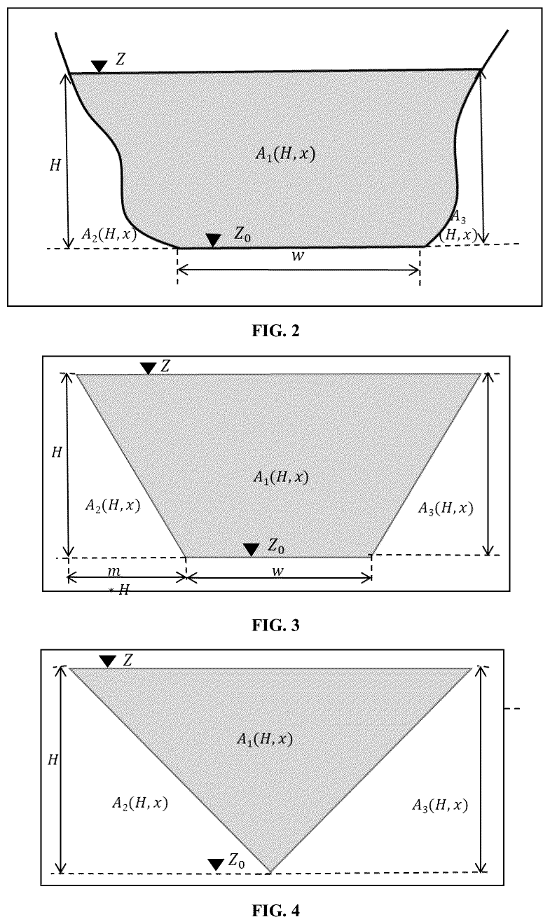

As shown in FIG. 2, the cross-section area of a general river is not only related to its location, but also to water depth. The x-axis is set along the direction of the river flow, and set the cross-section area as A₁(H, x), the length of a river as L, the surface area a river as A, the water depth as H. The volume of the water body in the river course is calculated as V=∫₀^{L}A₁(H, x)dx with the cross-section area as the base; at the same time, the volume is calculated with the water surface area as the base, and if the remaining triangular areas on both sides are A₂(H, x) and A₃(H, x), then the expression of the volume of the water body in the river course is V=AH−∫₀^{L} A₂(H, x)dx−∫₀^{L} A₃(H, x)dx; if the volume of water at the same time is the same, the first mathematical model of water depth-water surface area can be obtained as follows:

$$H = ( {\int }_{0}^{L} {A}_{1} ( H , x ) dx + {\int }_{0}^{L} ( {A}_{2} ( H , x ) + {A}_{3} ( H , x ) ) dx ) / A ;$$

wherein, H is the water depth, L is the length of a river course, A₁(H, x) is the water flowing cross-section area; x is the flow path; A₂(H, x) and A₃(H, x) are the area of the triangle at two sides; A is the water surface area.

Step (2), calculating the relation function between the water flowing cross-section area and the water depth as well as the flow path of the river course and a relation function between the area of the triangle at two sides and the water depth as well as the flow path of the river course based on the type of the river course, and substituting the relation functions into the first mathematical model of water depth-water surface area to obtain the second mathematical model of water depth-water surface area.

The type of the river course includes the trapezoidal cross-section river course, as shown in FIG. 3, and the triangular river course, as shown in FIG. 4.

Assuming the bottom width of the river course is w and the slope coefficient of the river course is m, the relation function between the water flowing cross-section area and the water depth as well as the flow path of the trapezoidal cross-section river course is as follows:

$${A}_{1} ( H , x ) = ( w + mH ) * H ;$$

wherein, A₁(H, x) is the water flowing cross-section area; w is the bottom width of a river course; m is the slope coefficient of a river course; H is the water depth.

The relation function between the area of the triangle at two sides and the water depth as well as the flow path of the trapezoidal cross-section river course is as follows:

$${A}_{2} ( H , x ) = {A}_{3} ( H , x ) = \frac{1}{2} * H * mH ;$$

wherein, A₂(H, x) and A₃(H, x) are the area of the triangle at two sides.
the second mathematical model of water depth-water surface area of the trapezoidal cross-section river course is as follows:

$$H = \frac{A - wL}{2 mL} ;$$

wherein, H is the water depth; A is the water surface area; w is the bottom width of a river course; L is the length of a river course; m is the slope coefficient of a river course.

The relation function between the water flowing cross-section area and the water depth as well as the flow path of the triangular river course is as follows:

$${A}_{1} ( H , x ) = ( mH ) * H ;$$

wherein, A₁(H, x) is the water flowing cross-section area; m is the slope coefficient of a river course; H is the water depth.

The relation function between the area of the triangle at two sides and the water depth as well as the flow path of the triangular river course is as follows:

$${A}_{2} ( H , x ) = {A}_{3} ( H , x ) = \frac{1}{2} * H * mH ;$$

wherein, A₂(H, x) and A₃(H, x) are the area of the triangle at two sides.
the second mathematical model of water depth-water surface area of the triangular river course is as follows:

$$H = \frac{A}{2 mL} ;$$

wherein, H is the water depth; A is the water surface area; m is the slope coefficient of a river course; L is the length of a river course.

Step (3), transforming the second mathematical model of water depth-water surface area into the mathematical model of water level-water surface area based on the relationship between water level and water depth; solving the unknowns in the mathematical model of water level-water surface area combined with the relationship between water level and water surface area obtained by remote sensing, and substituting the unknowns into the second mathematical model of water depth-water surface area to obtain the third mathematical model of water depth-water surface area.

The relationship between water level and water depth is as follows:

$$Z = H + {Z}_{0} ;$$

wherein, Z is the water level; H is the water depth; Z₀ is the bottom elevation of trench.

The mathematical model of water depth-water surface area of the trapezoidal cross-section river course is as follows:

$$Z = \frac{A}{2 mL} - \frac{w}{2 m} + {Z}_{0} ;$$

wherein, Z is the water level; A is the water surface area; m is the slope coefficient of a river course; L is the length of a river course; w is the bottom width of a river course; Z₀ is the bottom elevation of trench.

The mathematical model of water depth-water surface area of the triangular river course is as follows:

$$Z = \frac{A}{2 mL} + {Z}_{0} ;$$

wherein, Z is the water level; A is the water surface area; m is the slope coefficient of a river course; L is the length of a river course; Z₀ is the bottom elevation of trench.
the solving the unknowns in the mathematical model of water level-water surface area combined with the relationship between water level and water surface area obtained by remote sensing based on the relationship between water level and water depth specifically is as follows:
assuming that the corresponding parts of the mathematical model of water level-water surface area and the relationship between water level and water surface area are equal, the unknowns in the mathematical model of water level-water surface area can be solved as follows.

The embodiments of the present disclosure adopt a total of 40 Sentinel-2 remote sensing images from 2019 to 2022 to extract the water surface area of the research area, and combine them with the measured water level at hydrological stations during the same period as the remote sensing images to establish a water level water surface area relationship. The water level-water surface area relationship obtained from remote sensing is as follows:

$$Z = 7 * 1 {0}^{- 6} * A + 22.472 ;$$

wherein, Z is the water level; A is the water surface area.

There are three unknowns in the second mathematical model of the water depth-water surface area of a trapezoidal cross-section river course, including the slope coefficient of the river course m, the bottom width of the river course w, and the length of the river course L. Assuming that the corresponding parts of the mathematical model of water level-water surface area of the trapezoidal cross-section river course and the relationship between water level and water surface area are equal, that was

$$\frac{A}{2 mL} = 7 * 1 {0}^{- 6} * A , - \frac{w}{2 m} + {Z}_{0} = 22.472 ,$$

the length L of the river was extracted as 2500 meters using remote sensing images. The bottom width w of the river course was approximated by selecting remote sensing images during the dry season and using the ratio of the water surface area to the length of the river course to obtain a bottom width of 75.16 meters. The slope coefficient of the river course was solved to be 26.946, which was substituted into the second mathematical model of water depth-water surface area of the trapezoidal cross-section river course, and the third mathematical model of water depth-water surface area of the trapezoidal cross-section river course was obtained, as follows:

$$H = \frac{A - 187900}{134730} ;$$

wherein, H is the water depth; A is the water surface area.

There are three unknowns in the second mathematical model of the water depth-water surface area of a triangular river course, including the slope coefficient of the river course m and the length of the river course L. Assuming that the corresponding parts of the mathematical model of water level-water surface area of the trapezoidal cross-section river course and the relationship between water level and water surface area are equal, that was

$$\frac{A}{2 mL} = 7 * 1 {0}^{- 6} * A , {Z}_{0} = 22.4 \; 72 ,$$

the length L of the river was extracted as 2500 meters using remote sensing images, the slope coefficient of the river course was solved to be 26.946, which was substituted into the second mathematical model of water depth-water surface area and the third mathematical model of water depth-water surface area was obtained, as follows:

$$H = \frac{A}{134730} ;$$

wherein, H is the water depth; A is the water surface area.

Step (4), substituting the water surface area extracted by the remote sensing into the third mathematical model of water depth-water surface area to obtain the water depth of the river course.

Based on the third mathematical model of water depth-water surface area of the trapezoidal cross-section river course and the triangular cross-section river course, combined with remote sensing extraction of water surface area, the simulated water depth H_{simulated} and the measured water depth is H_{measured} are calculated. At this time, the absolute error absolute value is δ=|H_{simulated}−H_{measured}|, and the average absolute error is δ̅=δ/N, wherein N is the number of samples. The average absolute error of simulated water depth in trapezoidal cross-section river course is 0.03 meters, and the average absolute error of simulated water depth in triangular cross-section river course is 0.57 meters.

The example of the present disclosure discloses an inversion method of river course depth based on a mathematical model and remote sensing of water depth-water surface area. The mathematical model of water depth-water surface area is constructed based on the relationship between the water flowing cross-section area and the water depth as well as the flow path and the relationship between the area of the triangle at two sides and the water depth as well as the flow path, the unknowns in the mathematical model are solved by combining with the relationship between water level and water surface area obtained by remote sensing to obtain the relationship between the average water depth and water surface area. Based on this, by substituting the water surface area, the inversion of the average water depth of the river course can be achieved. Is not only improves the representativeness of water depth values, but also overcomes the difficulty of utilizing wave bands to invert the water depth of high sediment content water bodies.

Various embodiments of the present specification are described in a progressive manner, and each embodiment focuses on the description that is different from the other embodiments, and the same or similar parts between the various embodiments are referred to with each other. For the device disclosed in the embodiment, since it corresponds to the method disclosed in the embodiment, the description is relatively simple, and the correlation is described with reference to the method part.

The above description of the disclosed embodiments enables those skilled in the art to implement or use the present disclosure. Various amendments to the embodiments will be apparent to those skilled in the art. The general principles defined herein may be implemented in other embodiments without departing from the spirit or scope of the disclosure. Therefore, the present disclosure will not be limited to the embodiments shown herein but is to be accorded the widest scope consistent with the principles and novel features disclosed herein.

1. An inversion method of river course depth based on a mathematical model and remote sensing of water depth-water surface area, comprising:
step (0): measuring a water surface area of the river course via the remote sensing and measuring water level of the river course at hydrological stations at the river course;
step (1): constructing a first mathematical model of water depth-water surface area of the river course;
step (2): calculating a relation function between water flowing cross-section area and water depth as well as flow path of the river course and a relation function between area of a triangle at two sides and water depth as well as flow path of the river course based on a type of the river course, and substituting the relation functions into the first mathematical model of water depth-water surface area to obtain a second mathematical model of water depth-water surface area;
step (3): transforming the second mathematical model of water depth-water surface area into a mathematical model of water level-water surface area based on a relationship between water level and water depth; solving unknowns in the mathematical model of water level-water surface area combined with a relationship between the water level and the water surface area obtained by the remote sensing, and substituting the unknowns into the second mathematical model of water depth-water surface area to obtain a third mathematical model of water depth-water surface area; and
step (4): substituting water surface area extracted by the remote sensing into the third mathematical model of water depth-water surface area to obtain the water depth of the river course, and outputting the water depth of the river course;
wherein in the step (1), the first mathematical model of water depth-water surface area is as follows:
$$H = ( {\int }_{0}^{L} {A}_{1} ( H , x ) d x + {\int }_{0}^{L} ( {A}_{2} ( H , x ) + {A}_{3} ( H , x ) ) dx ) / A ;$$
wherein, H is the water depth, L is a length of the river course, A₁(H, x) is the water flowing cross-section area; x is the flow path; A₂(H, x) and A₃(H, x) are the area of the triangle at two sides; and A is the water surface area;
in the step (2), the type of the river course comprises a trapezoidal cross-section river course and a triangular river course;
the relation function between the water flowing cross-section area and the water depth as well as the flow path of the trapezoidal cross-section river course is as follows:
$${A}_{1} ( H , x ) = ( w + m H ) * H ;$$
wherein, A₁(H, x) is the water flowing cross-section area; w is a bottom width of the river course; m is a slope coefficient of the river course; and H is the water depth;
the relation function between the area of the triangle at two sides and the water depth as well as the flow path of the trapezoidal cross-section river course is as follows:
$${A}_{2} ( H , x ) = {A}_{3} ( H , x ) = \frac{1}{2} * H * mH ;$$
wherein, A₂(H, x) and A₃(H, x) are the area of the triangle at two sides;
the second mathematical model of water depth-water surface area of the trapezoidal cross-section river course is as follows:
$$H = \frac{A - wL}{2 mL} ;$$
wherein, H is the water depth; A is the water surface area; w is the bottom width of the river course; L is the length of the river course; and m is the slope coefficient of the river course;
the second mathematical model of water depth-water surface area of the triangular river course is as follows:
$$H = \frac{A}{2 mL} ;$$
wherein, H is the water depth; A is the water surface area; m is the slope coefficient of the river course; and L is the length of the river course;
based on the remote sensing, the relationship between water level-water surface area is obtained:
based on remote sensing images, extracting the water surface area of a research area, and combining the water surface area of the research area with the measured water level at the hydrological stations during a same period as the remote sensing images to establish the relationship between water level and water surface area;
the unknowns in the mathematical model of water level-water surface area are:
the unknowns in the mathematical model of water level-water surface area of the trapezoidal cross-section river course are the slope coefficient of the river course m, the bottom width of the river course w, and the length of the river course L;
the unknowns in the mathematical model of water level-water surface area of the triangular river course are the slope coefficient of the river course m and the length of the river course L.

2. The inversion method of river course depth based on the mathematical model and remote sensing of water depth-water surface area according to claim 1, wherein in the step (3), the relationship between water level and water depth is as follows:
$$Z = H + {Z}_{0} ;$$
wherein, Z is the water level; H is the water depth; and Z₀ is a bottom elevation of trench.

3. The inversion method of river course depth based on the mathematical model and remote sensing of water depth-water surface area according to claim 1, wherein in the step (3), the solving the unknowns in the mathematical model of water level-water surface area combined with the relationship between water level and water surface area obtained by remote sensing based on the mathematical model of water level-water surface area specifically is as follows:
assuming that corresponding parts of the mathematical model of water level-water surface area and the relationship between water level and water surface area are equal, solving the unknowns in the mathematical model of water level-water surface.
